(19) United States
(12) Patent Application Publication
(10) Pub. No.: US 2026/0038573 A1
(43) Pub. Date: Feb. 5, 2026

(54) Usage-Based-Disturbance Pattern Detector

(71) Applicant: Micron Technology, Inc., Boise, ID (US)

(72) Inventors: Yang Lu, Boise, ID (US); Michael A. Shore, Boise, ID (US)

(73) Assignee: Micron Technology, Inc., Boise, ID (US)

(21) Appl. No.: 19/261,333

(22) Filed: Jul. 7, 2025

Related U.S. Application Data
(60) Provisional application No. 63/677,878, filed on Jul. 31, 2024.

(51) Int. Cl. G11C 11/4078; G11C 11/4072; G11C 11/408

(52) U.S. Cl. CPC G11C 11/4078; G11C 11/4072; G11C 11/408

(57) ABSTRACT

Apparatuses and techniques for detection of usage-based-disturbance (UBD) patterns and for performance of an associated operation are described. To enable detection of UBD patterns, a memory device including a plurality of rows of memory cells includes UBD pattern detection circuitry. The UBD pattern detection circuitry detects UBD patterns by comparison of a received row address to a previously received row address. The memory device is configured to update a UBD count using a first value if the UBD pattern detection circuitry does not detect a UBD pattern and to update the UBD count using a second value, which is different from the first value, if the UBD pattern detection circuitry does detect a UBD pattern. The UBD pattern detection circuitry may be configured to detect whether a UBD pattern has been applied by comparing the received row address to a plurality of previously received row addresses.

### CROSS-REFERENCE TO RELATED APPLICATION(S)

This application claims the benefit of U.S. Provisional Patent Application No. 63/677,878 filed on 31 Jul. 2024, the disclosure of which is hereby incorporated by reference herein in its entirety.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses of and techniques for usage-based-disturbance pattern detection are described with reference to the following drawings. The same numbers are used throughout the drawings to reference like features and components:

FIG. 1 illustrates example apparatuses that can implement aspects of usage-based-disturbance pattern detection;

FIG. 2 illustrates example computing systems that can implement aspects of usage-based-disturbance pattern detection;

FIG. 3 illustrates example approaches to storing data within rows of a memory array to support usage-based-disturbance pattern detection;

FIG. 4 illustrates an example memory device in which aspects of usage-based-disturbance pattern detection can be implemented;

FIG. 5 illustrates an example arrangement of circuits that can implement aspects of usage-based-disturbance pattern detection;

FIG. 6 illustrates aspects of an example usage-based-disturbance mitigation operation that is performed by an example usage-based-disturbance mitigation circuit;

FIG. 7-1 illustrates an arrangement of components of an example UBD pattern detection circuit that can implement aspects of usage-based-disturbance pattern detection;

FIG. 7-2 illustrates an arrangement of components of another example UBD pattern detection circuit that can implement aspects of usage-based-disturbance pattern detection;

FIG. 8 illustrates an example implementation of a UBD pattern detector that can implement aspects of usage-based-disturbance pattern detection;

FIG. 9 is a flow chart illustrating example aspects associated with UBD pattern detection;

FIG. 10 is a flow chart illustrating example aspects associated with UBD pattern detection; and

FIG. 11 is a flow chart illustrating example aspects associated with UBD pattern detection.

### DETAILED DESCRIPTION

### Overview

Processors and memory work in tandem to provide features to users of computers and other electronic devices. As processors and memory operate more quickly together in a complementary manner, an electronic device can provide enhanced features, such as high-resolution graphics and artificial intelligence (AI) analysis. Some applications, such as those for financial services, medical devices, and advanced driver assistance systems (ADAS), can also demand more-reliable memories. These applications use increasingly reliable memories to limit errors in financial transactions, medical decisions, and object identification, respectively. In some implementations, however, more-reliable memories can sacrifice bit density, power efficiency, and simplicity.

Generally, a memory device is expected to service memory requests from a host device within predetermined time periods and/or with predictable delay durations. These constraints mean that the memory device prioritizes memory requests from an external entity, such as a memory controller of a host device. A modern memory device, however, has additional expectations beyond servicing memory requests. For example, to create a more reliable memory, a memory device is expected to combat attacks from bad actors, such as usage-based-disturbance (UBD) attacks, which are described below. Thus, a memory device may perform usage-based-disturbance mitigation operations in conjunction with servicing memory requests.

It can be challenging, however, to adequately mitigate UBD attacks against memories. For example, a particular UBD attack may be performed in a pattern in which the standard mitigation techniques may not account for the patterned attack. Accordingly, this document describes apparatuses and techniques for detecting UBD patterns and responding accordingly to protect data stored in the memory.

To meet demands for physically smaller memories, memory devices can be designed with higher chip densities for the memory cells. Increasing chip density, however, can increase electromagnetic coupling between proximate rows of memory cells due, at least in part, to a shrinking distance between these rows. With this undesired electromagnetic coupling (e.g., capacitive coupling), activation (or charging) of a first row of memory cells can sometimes negatively impact the integrity of the digital values stored in a nearby second row of memory cells. This phenomenon is referred to herein as usage-based-disturbance. Activation of the first row can generate interference, or crosstalk, which causes the second row to experience a voltage fluctuation. In some instances, this voltage fluctuation can cause a state, or value, of a memory cell in the second row to be incorrectly determined by a sense amplifier. Consider an example in which a state of a memory cell in the second row is a logical “1” (e.g., a high voltage). In this example, the voltage fluctuation can cause a sense amplifier to incorrectly determine the state of the memory cell to be a logical “0” (e.g., a low voltage) instead of a logical “1.” Left unchecked, this interference can lead to memory errors or data loss within the memory device.

In some circumstances, a particular row of memory cells is activated repeatedly in an unintentional or intentional manner, which can be part of a malicious act. Such a row that is repeatedly activated is referred to herein as an aggressor row. Consider, for instance, that memory cells in an R^{th} row are subjected to repeated activation, which causes one or more memory cells in a proximate row (e.g., an adjacent row) to change states. Here, a proximate row can include another row within the following example rows: an R+1 row, which is an adjacent row; an R+2 row; an R−1 row, which is another adjacent row; and/or an R−2 row. These proximate rows are referred to herein as victim rows. The effect of changed memory states is referred to as a usage-based-disturbance. The occurrence of usage-based-disturbance can lead to the corruption or changing of contents within the affected row of memory. As described herein below, to combat the negative effects of usage-based-disturbance, a memory device can perform usage-based-disturbance mitigation operations. Further, a memory device may be configured to detect patterns of UBD attacks and perform adequate UBD mitigation operations to mitigate a UBD patterned attack.

A UBD attack may be applied in a pattern to a victim row of a plurality of rows of memory cells of a memory device. The UBD pattern may potentially increase negative effects on the victim row. One such UBD pattern may be an alternating double-side attack of the victim row. In other words, the two rows adjacent to the victim row may be alternately activated, which activation pattern can potentially increase the negative effect of the UBD attack. Another potential UBD attack pattern may be sequentially activating twice the first adjacent row to the victim row and then sequentially activating twice the second adjacent row to the victim row. These UBD patterns are discussed for illustrative purposes, and other UBD patterns may be applied to a memory device as would be appreciated by one of ordinary skill in the art having the benefit of this disclosure.

A memory device may be configured to detect whether a UBD pattern has been applied to a row of a plurality of rows of memory cells of the memory device and to mitigate a UBD attack when a UBD pattern has been detected. The memory device may include UBD pattern detection circuitry configured to detect if a UBD pattern has been applied. Upon detection, the UBD pattern detection circuitry may be configured to appropriately update a UBD count. For example, the UBD pattern detection circuitry may be configured to update the UBD count using a first value if no UBD pattern is detected and to update the UBD count using a second value if a UBD pattern is detected, with the second value differing from the first value. In these manners, a victim row that is subjected to application of a UBD pattern at an aggressor row can be mitigated sooner by increasing the UBD counter at a faster rate.

### EXAMPLE OPERATING ENVIRONMENTS

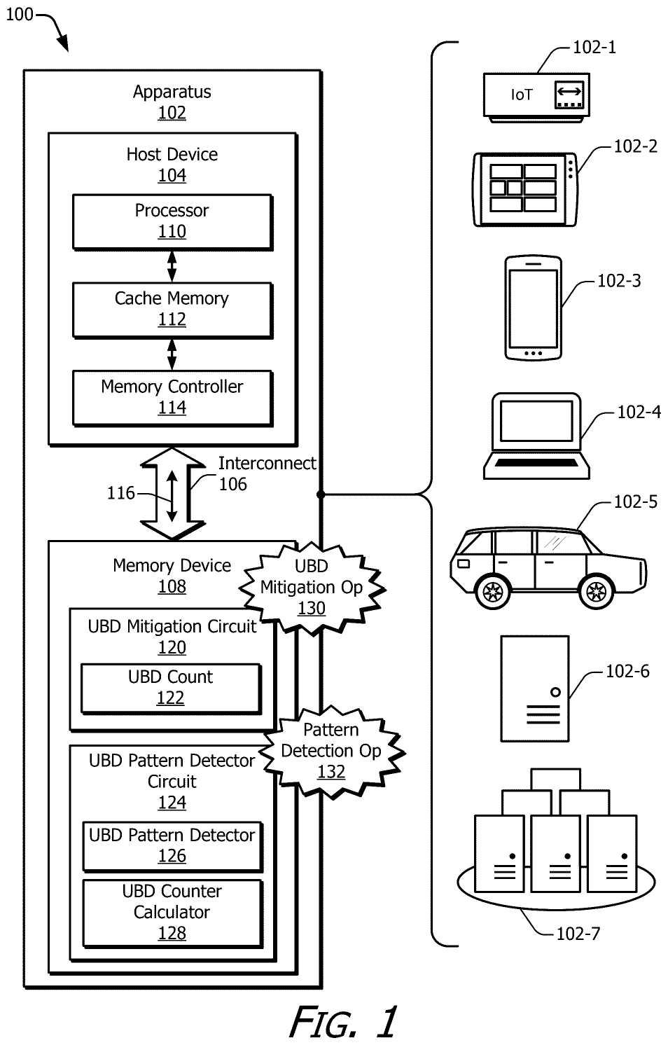

FIG. 1 illustrates, at 100 generally, an example operating environment including an apparatus 102 that can implement aspects of usage-based-disturbance pattern detection. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7. The server computer 102-6 or the server cluster 102-7 may be part of cloud computing infrastructure, a data center, a portion thereof (e.g., a printed circuit board (PCB)), and so forth. Other examples of the apparatus 102 include a wearable device (e.g., a smartwatch or intelligent glasses), an entertainment device (e.g., a set-top box, video dongle, smart television, a gaming device), a desktop computer, a motherboard, a server blade, a consumer appliance, a vehicle, a drone, industrial equipment, a security device, a medical device, a sensor, or the electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and at least one memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit, graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) or synchronous memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests (e.g., read data or write confirmation) that are received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., unidirectional bus, bidirectional bus, or memory bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity or lower cost relative to memory at higher hierarchical levels. Accordingly, the memory device 108 can form at least part of the main memory of the apparatus 102. Additionally, or alternatively, the memory device 108 may form at least part of a cache memory, a storage memory, or an SoC of the apparatus 102.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a printed circuit board (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114.

Thus, this document describes with reference to FIG. 1 an example computing system architecture having at least one host device 104 coupled to a memory device 108. Two or more memory components (e.g., modules, dies, bank groups, or banks) may share the electrical paths or couplings of the interconnect 106 that can extend between the host device 104 and the memory device 108. The interconnect 106 can include at least one command-and-address bus (CA bus) and at least one data bus (DQ bus), which are not separately depicted. The command-and-address bus can transmit addresses and commands from the memory controller 114 of the host device 104 to the memory device 108. In some cases, the command-and-address bus may exclude the propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

In example implementations, the memory device 108 includes at least one usage-based-disturbance mitigation circuit 120 (UBD mitigation circuit 120) and at least UBD pattern detector circuit 124. The UBD mitigation circuit 120 includes at least one UBD count 122 that indicates an activation count of each row of a plurality of rows of memory cells of a memory bank. The UBD pattern detector circuit 124 includes a UBD pattern detector 126 and a UBD counter calculator 128 as described herein. The UBD mitigation circuit 120 and the UBD pattern detector circuit 124 can each be implemented using, for example, hardware that includes programmable logic circuitry, fixed logic circuitry, or some combination thereof. These circuits can be arranged or organized in any manner. For example, two or more circuits can be combined, or one circuit may incorporate or encompass one or more other circuits. For instance, the UBD pattern detector 126 can be fully or partially integrated within one or more other circuits, such as the UBD pattern detector circuit 124, or the UBD pattern detector 126 can be implemented separately.

In example operations, the UBD mitigation circuit 120 mitigates usage-based-disturbance for one or more banks that are associated with (e.g., that are part of) the memory device 108 using at least one usage-based-disturbance mitigation operation 130 (UBD mitigation operation 130). This mitigation can include detecting a condition associated with usage-based-disturbance, such as the presence of an aggressor row, and initiating a refresh of one or more victim rows associated with the detected condition of the aggressor row. The UBD mitigation circuit 120 can employ various strategies for detecting and mitigating usage-based-disturbance conditions.

The UBD pattern detector 126 may be configured to detect patterns or behaviors associated with usage-based-disturbance during a pattern detection operation 132. For example, the UBD pattern detector 126 may be configured to detect a pattern in which the aggressor row alternates between rows adjacent to a victim row of memory cells. As another example of a pattern associated with usage-based-disturbance, the UBD pattern detector 126 may be configured to detect when an aggressor row, adjacent to a first side of a victim row of memory cells, is activated twice in a row and then a second aggressor row, adjacent to a second side of the victim row of memory cells, is activated twice in a row. These UBD patterns are discussed for illustrative purposes, for the UBD pattern detector 126 may be configured to detect various patterns and/or behaviors associated with a usage-based-disturbance attack as would be appreciated by one of ordinary skill in the art having the benefit of this disclosure.

The UBD counter calculator 128 may be configured to update a UBD count 122 based on the detection, by the UBD pattern detector 126, of a UBD pattern (e.g., a repeated operation and/or behavior). The UBD counter calculator 128 may be configured to increase the UBD count 122 using a first value (e.g., by a first value) if no pattern is detected and to increase the count using a second value (e.g., by a second value) if a UBD pattern is detected by the UBD pattern detector 126. In some implementations, the second value is greater than the first value. In one implementation, the first value may be one (1), and the second value may be two (2). In other implementations, the UBD counter calculator 128 may be configured to increase the UBD count 122, decrease the UBD count 122, or overwrite the UBD count 122 based on the detection of a UBD pattern by the UBD pattern detector 126.

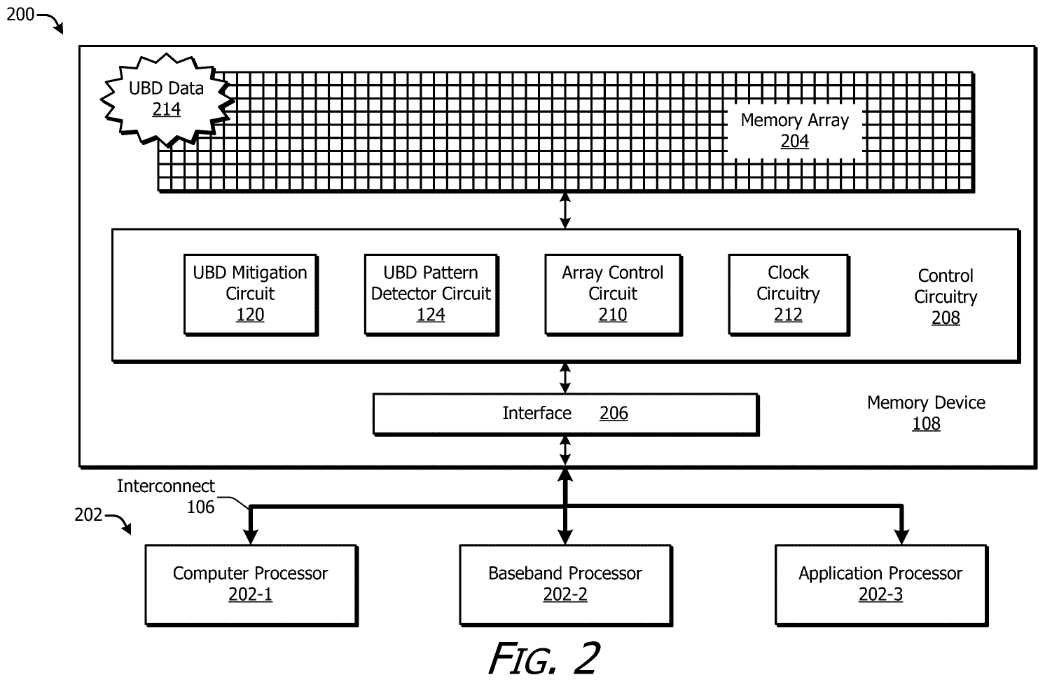

Each of these circuits can be implemented at a local-bank level, at a global-bank level (e.g., a global level, a central level, or a chip level), or at a combination of a local-bank level and a global-bank level. Next, however, other components of the memory device 108 are described with reference to FIG. 2 in the context of an example computing system.

FIG. 2 illustrates examples of a computing system 200 that can implement aspects of usage-based-disturbance pattern detection. In some implementations, the computing system 200 includes at least one memory device 108, at least one interconnect 106, and at least one processor 202. The memory device 108 can include, or be associated with, at least one memory array 204, at least one interface 206, and control circuitry 208 (or periphery circuitry or central circuitry) operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 208 may be components on a single semiconductor die or on separate semiconductor dies. The memory array 204 or the control circuitry 208 may also be distributed across multiple dies. This control circuitry 208 may additionally or alternatively manage traffic on a bus that is separate from the interconnect 106.

The control circuitry 208 can include various components that the memory device 108 can use to perform various operations. These operations can include communicating with other devices, managing memory performance, performing refresh operations (e.g., self-refresh operations or auto-refresh operations), and performing memory read or write operations. In the depicted configuration, the control circuitry 208 includes the UBD mitigation circuit 120, the UBD pattern detector circuit 124, at least one array control circuit 210, and at least one instance of clock circuitry 212. In some implementations, the UBD mitigation circuit 120 and the UBD pattern detector circuit 124 are part of the control circuitry 208, as shown in FIG. 2. In other implementations, the UBD mitigation circuit 120 and the UBD pattern detector circuit 124, or some combination thereof, are considered at least partly separate from the control circuitry 208 from a logical or physical perspective.

The array control circuit 210 can include circuitry that provides command decoding, address decoding, input/output functions, amplification circuitry, power supply management, power control modes, and other functions. The clock circuitry 212 can synchronize various memory components with one or more external clock signals provided over the interconnect 106, including a command-and-address clock or a data clock. The clock circuitry 212 can also include an internal clock generator or use an internal clock signal to synchronize memory components. The clock circuitry 212 may further provide timer functionality.

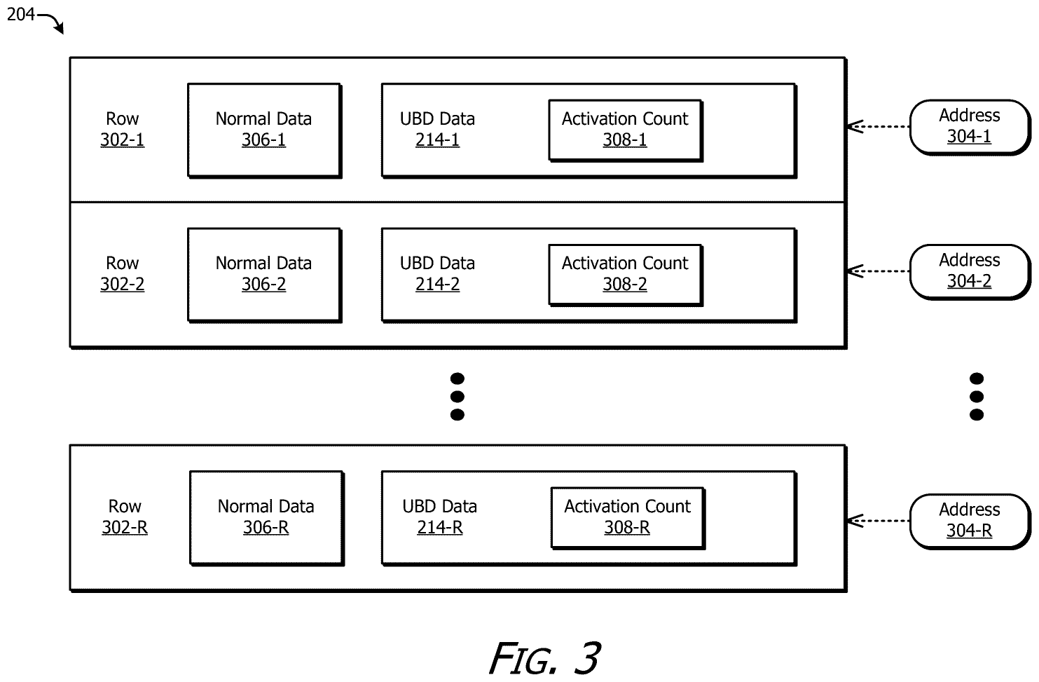

The UBD mitigation circuit 120 can be coupled to a set of memory cells within the memory array 204 that store usage-based-disturbance data 214 (UBD data 214). The usage-based-disturbance data 214 can include information such as an activation count, or UBD count 122, which represents a quantity of times one or more rows within the memory array 204 have been activated (or accessed) by the memory device 108. In example implementations, each row of the memory array 204 includes or corresponds to a subset of memory cells that stores the usage-based-disturbance data 214 associated with that row, which is further described with reference to FIG. 3. The UBD pattern detector circuitry 124 can be coupled to any row of multiple rows of the memory array 204.

The interface 206 can couple the control circuitry 208 or the memory array 204 directly or indirectly to the interconnect 106. In some implementations, the UBD mitigation circuit 120, the UBD pattern detector circuit 124, the array control circuit 210, and the clock circuitry 212 can be part of a single component (e.g., the control circuitry 208). In other implementations, one or more of the UBD mitigation circuit 120, the UBD pattern detector circuit 124, the array control circuit 210, or the clock circuitry 212 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and a processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a printed circuit board, memory card, memory stick, memory module (e.g., a single in-line memory module (SIMM) or dual in-line memory module (DIMM)), or memory integrated circuit, just to name a few examples. Separate physical components may be located together within the same housing of an electronic device or may be distributed over a server rack, a data center, and so forth. Alternatively, the memory device 108 may be integrated with other physical components, including the host device 104 or the processor 202, by being combined on a printed circuit board or combined in a single package or an SoC.

As shown in FIG. 2, the processors 202 may include a computer processor 202-1, a baseband processor 202-2, and an application processor 202-3, which are coupled to the memory device 108 through the interconnect 106. The processors 202 may include or form a part of a central processing unit (CPU), graphics processing unit (GPU), system-on-chip (SoC), application-specific integrated circuit (ASIC), or field-programmable gate array (FPGA). In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). Examples of the memory array 204 are further described with reference to FIG. 3.

FIG. 3 illustrates example approaches to storing data within rows of a memory array 204 to support usage-based-disturbance mitigation and usage-based-disturbance pattern detection. As illustrated, the memory array 204 includes multiple rows 302 of memory cells. For example, the memory array 204 can include rows 302-1, 302-2, . . . , 302-R, where R represents a positive integer. Each row 302 is respectively associated with an address 304 (e.g., a row address, a memory row address, or a memory address) of multiple addresses 304-1, 304-2, . . . , 304-R. For example, a first row 302-1 has a first address 304-1, a second row 302-2 has a second address 304-2, and an R^{th} row 302-R has an R^{th} address 304-R.

Each of the rows 302 can store normal data 306 within a first subset of the memory cells associated with that row 302. The normal data 306 represents data that is read from or written to the memory device 108 during normal memory input/output operations (e.g., during normal read or write operations for user data). The normal data 306, for example, can include data that is transmitted by the memory controller 114 and is written to one or more rows 302 of the memory array 204.

In example implementations, in addition to the normal data 306, each of the rows 302 can store usage-based-disturbance data 214 within a second subset of the memory cells associated with that row 302. The usage-based-disturbance data 214 includes information that enables the UBD mitigation circuit 120 to mitigate the potential effects of usage-based-disturbance. In example aspects, the usage-based-disturbance data 214 includes an activation count 308. With the activation count 308, the memory device 108 can keep track of a quantity of accesses or activations of the corresponding memory row 302. In some example implementations, the usage-based-disturbance data 214 can also include a count of how many times a neighboring row (e.g., an adjacent or other proximate row) is refreshed in order to mitigate usage-based-disturbance. Each of these counts provides an example mechanism by which the memory device 108 can monitor for usage-based-disturbance and usage-based-disturbance patterns and determine when to refresh victim rows to reduce the risk of usage-based-disturbance corrupting data.

In the example shown in FIG. 3, the first row 302-1 stores first normal data 306-1 within a first subset of memory cells of the first row 302-1 and stores first usage-based-disturbance data 214-1 within a second subset of the memory cells of the first row 302-1. The first usage-based-disturbance data 214-1 includes a first activation count 308-1, which represents a quantity of times the first row 302-1 has been activated since a last refresh. As another example, the second row 302-2 stores second normal data 306-2 within a first subset of memory cells within the second row 302-2 and stores second usage-based-disturbance data 214-2 within a second subset of the memory cells within the second row 302-2. The second usage-based-disturbance data 214-2 includes a second activation count 308-2, which represents a quantity of times the second row 302-2 has been activated since a last refresh.

Additionally, the R^{th} row 302-R stores R^{th} normal data 306-R within a first subset of memory cells within the R^{th} row 302-R and stores R^{th} usage-based-disturbance data 214-R within a second subset of the memory cells within the R^{th} row 302-R. The R^{th} usage-based-disturbance data 214-R includes an R^{th} activation count 308-R, which represents a quantity of times the R^{th} row 302-R has been activated since a last refresh. Although UBD data 214 is depicted as being part of a respective corresponding row 302, UBD data 214 may be stored or disposed separately from the corresponding row 302 (e.g., in a separate array or subarray).

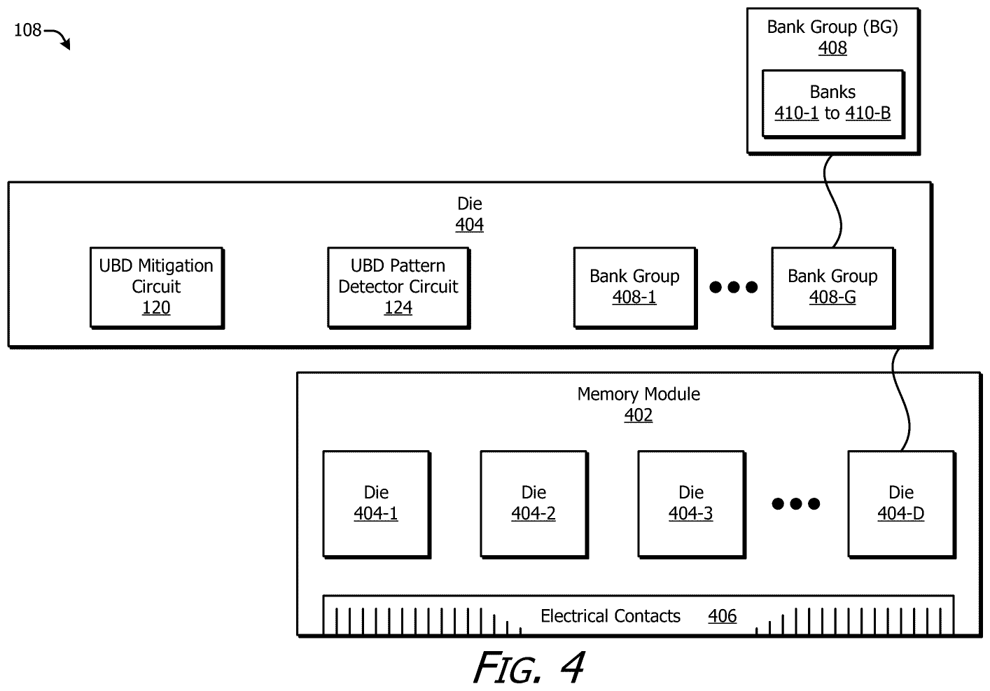

FIG. 4 illustrates an example memory device 108 in which aspects of usage-based-disturbance mitigation and UBD pattern detection can be implemented. As shown, the memory device 108 includes a memory module 402, which can include multiple dies 404. As illustrated, the memory module 402 includes a first die 404-1, a second die 404-2, a third die 404-3, and a D^{th} die 404-D, with D representing a positive integer. The memory module 402 can be a SIMM or a DIMM, for instance. As another example, the memory module 402 can interface with other components via a bus interconnect (e.g., a Peripheral Component Interconnect Express (PCIe®) bus). The memory device 108 illustrated in FIGS. 1 and 2 can correspond, for example, to a die 404, to multiple dies (or dice) 404-1 through 404-D, or to a memory module 402 with two or more dies 404. As shown, the memory module 402 can include one or more electrical contacts 406 (e.g., pins) to interface the memory module 402 to other components.

The memory module 402 can be implemented in various manners. For example, the memory module 402 may include a printed circuit board, and the multiple dies 404-1 through 404-D may be mounted or otherwise attached to the printed circuit board. The dies 404 (e.g., memory dies) may be arranged in a line or along two or more dimensions (e.g., forming a grid or array). The dies 404 may have a similar size to each other or may have different sizes. Generally, each die 404 may be similar to another die 404 or may be different in size, shape, data capacity, or control circuitries. The dies 404 may also be positioned on a single side or on multiple sides of the memory module 402.

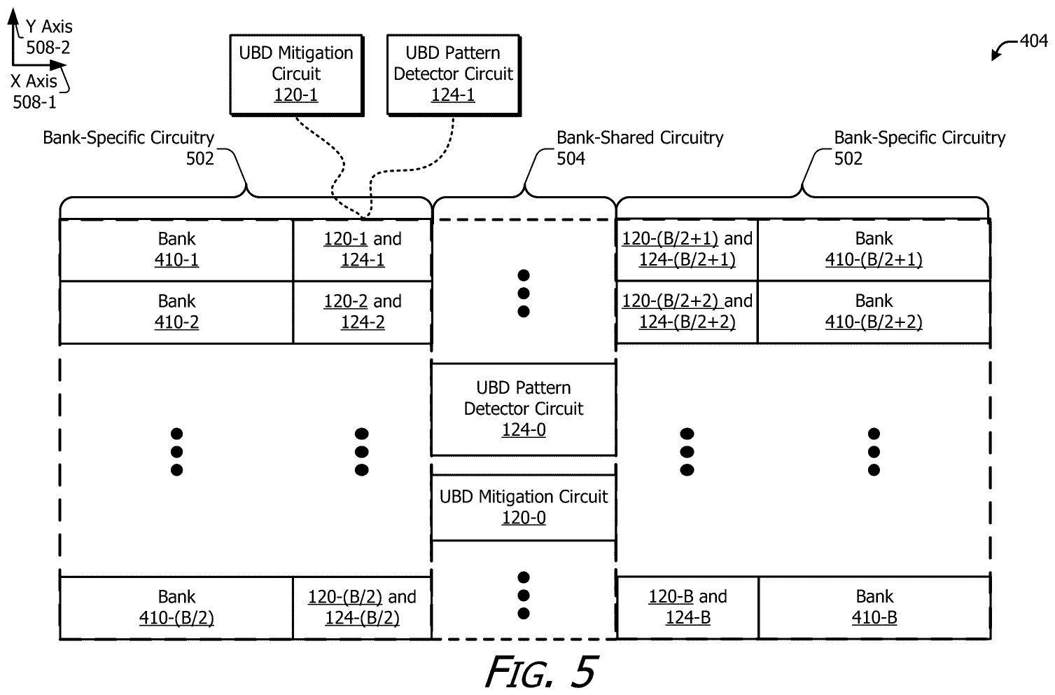

In example implementations, one or more of the dies 404-1 to 404-D include the UBD mitigation circuit 120, the UBD pattern detector circuit 124, and multiple bank groups 408-1 . . . 408-G, with G representing a positive integer. Each bank group 408 includes at least two banks 410, such as multiple banks 410-1 . . . 410-B, with B representing a positive integer. In some implementations, the die 404 includes multiple instances of the UBD mitigation circuit 120, each of which mitigates usage-based-disturbance across at least one of the banks 410. The die 404 also includes multiple instances of the UBD pattern detector circuit 124, each of which performs the UBD pattern and/or behavior detection for at least one respective corresponding bank 410. Generally, a given circuit can operate with respect to a single bank 410, multiple banks 410-1 to 410-B of a single bank group 408 (e.g., up to all banks of the bank group), multiple banks 410 distributed across two or more bank groups 408, a single bank group 408, multiple bank groups 408-1 to 408-G, all banks 410 on an IC chip (and thus all bank groups, if present), and so forth. Thus, each instance of a UBD mitigation circuit 120 or a UBD pattern detector circuit 124 can be implemented at a local-bank level, at a global-bank level (e.g., a global level, a central level, or a chip level), or at a combination of a local-bank level and a global-bank level. Example relationships between the banks 410-1 to 410-B, the UBD mitigation circuit 120, and the UBD pattern detector circuit 124 are further described with reference to FIG. 5.

### EXAMPLE TECHNIQUES AND HARDWARE

FIG. 5 illustrates an example arrangement of circuits that can implement aspects of usage-based-disturbance mitigation and UBD pattern detection on a die 404. As shown, the die 404 can include multiple instances of the UBD mitigation circuit 120 and multiple instances of the UBD pattern detector circuit 124. In example implementations, the die 404 includes bank-specific circuitry 502 and bank-shared circuitry 504. Bank-specific circuitry 502 includes components that are associated with a particular bank 410. For example, the bank-specific circuitry 502 includes banks 410-1, 410-2, . . . , 410-(B/2), 410-(B/2+1), 410-(B/2+2), . . . , 410-B; UBD mitigation circuits 120-1, 120-2, . . . , 120-(B/2), 120-(B/2+1), 120-(B/2+2), . . . , 120-B; and UBD pattern detector circuits 124-1, 124-2, . . . , 124-(B/2), 124-(B/2+1), 124-(B/2+2), . . . , 124-B.

The UBD mitigation circuits 120-1 to 120-B and the UBD pattern detector circuits 124-1 to 124-B are respectively coupled to the banks 410-1 to 410-B. In some cases, subsets of the banks 410-1 to 410-B are associated with different bank groups 408 (e.g., of FIG. 4). For example, the die 404 can include 32 banks 410-1 . . . 410-B (e.g., B equals 32 in this example). The 32 banks 410-1 to 410-B can form eight bank groups 408-1 . . . 408-G (e.g., G equals 8 in this example), with each bank group 408 therefore including four of the banks 410. In other cases, the banks 410-1 to 410-B may be part of, or otherwise associated with, a single bank group 408, or the memory die 404 may have no organization by bank group.

The bank-shared circuitry 504 includes components that are associated with multiple banks 410, such as two or more banks 410. These components can perform operations or provide instructions or commands that are associated with multiple banks 410. Example components of the bank-shared circuitry 504 may include at least one UBD mitigation circuit 120-0 and at least one UBD pattern detector circuit 124-0. The bank-shared instances of circuits, if present, can coordinate operations, initialize circuitry, or provide multi-bank control for respective functionalities. In some architectures, the bank-shared circuitry 504 can be positioned on an IC chip in a centralized portion of the chip. For instance, the bank-shared circuitry 504 can be positioned between two or more banks 410 to facilitate having signaling pathways to the multiple banks 410 with lengths that are more equal than if the bank-shared circuitry 504 were positioned on a far side of the multiple banks 410.

Further, on the die 404, the bank-specific circuitry 502 can be positioned on two (or more) opposite sides of the bank-shared circuitry 504. Explained another way, the bank-shared circuitry 504 can be centrally positioned on the die 404. As such, the UBD mitigation circuit 120-0 and the UBD pattern detector circuit 124-0 can be positioned closer to the center of the die 404 as compared to the edges of the die 404. Positioning the bank-shared circuitry 504 in the center enables signal routing between the bank-shared circuitry 504 and the bank-specific circuitry 502 to be simplified, shortened, or better equalized.

In some implementations, the UBD pattern detector circuit 124 can be organized into different circuitries. For example, at least one bank-shared circuit instance for UBD pattern detection, which is identified as the UBD pattern detector circuit 124-0, can provide centralized control at a global-bank level. This bank-shared UBD pattern detector circuit 124-0 can report detection of UBD patterns at the global or bank-shared level (e.g., for memorialization to communicate such detections to a host device). Multiple bank-specific circuit instances for UBD pattern detection are identified as the multiple UBD pattern detector circuits 124-1 to 124-B. Each bank-specific UBD pattern detector circuit 124-x of the multiple UBD pattern detector circuits 124-1 to 124-B can be associated with a respective bank 410-x of the multiple banks 410-1 to 410-B. In such cases, a respective UBD pattern detector circuit 124-x can be disposed physically proximate to the respective bank 410-x or can be responsible for performing UBD pattern detection operations 132 on the respective bank 410-x (including both in an interpretation of “or” as being an “inclusive-or,” which interpretation is permitted herein). In the architecture of FIG. 5, each respective UBD mitigation circuit 120 that corresponds to a respective bank 410-x can be referred to as a bank-specific usage-based-disturbance mitigation circuit 120-x.

Consider a first axis 508-1 (e.g., the X axis 508-1) and a second axis 508-2 (e.g., the Y axis 508-2), which is perpendicular to the first axis 508-1. In FIG. 5, the first axis 508-1 is depicted as a “horizontal” axis, and the second axis 508-2 is depicted as a “vertical” axis. Components of the bank-shared circuitry 504 are distributed across the second axis 508-2. A first set of the banks (e.g., banks 410-1 to 410-(B/2)) are arranged along the second axis 508-2 on a “left” side (as depicted) of the bank-shared circuitry 504. A second set of the banks (e.g., banks 410-(B/2+1) to 410-B) are arranged along the second axis 508-2 on a “right” side of the bank-shared circuitry 504. The bank-specific UBD mitigation circuits 120-1 to 120-B and the bank-specific UBD pattern detector circuits 124-1 to 124-B are positioned between the corresponding banks 410-1 to 410-B and the bank-shared circuitry 504. By positioning the bank-shared UBD pattern detector circuit 124-0 and the bank-shared UBD mitigation circuit 120-0 (if bank-shared instances are present) in a centralized location between the bank-specific UBD mitigation circuits 120-1 to 120-B and the bank-specific UBD pattern detector circuits 124-1 to 124-B, this architecture makes routing signal paths easier between the bank-shared UBD pattern detector circuit 124-0 and the bank-shared UBD mitigation circuit 120-0 of the bank-shared circuitry 504 and the various circuits of the bank-specific circuitry 502. Thus, one or more instances of the UBD mitigation circuit 120 and one or more instances of the UBD pattern detector circuit 124 can be implemented at a local-bank level (e.g., as the bank-specific UBD mitigation circuits 120-1 to 120-B and the bank-specific UBD pattern detector circuits 124-1 to 124-B), at a global-bank level (e.g., at a global level, a central level, or a chip level as the bank-shared UBD pattern detector circuit 124-0 and the bank-shared UBD mitigation circuit 120-0), or at a combination of a local-bank level and a global-bank level. The principles for usage-based-disturbance mitigation and usage-based-disturbance pattern detection, however, can be implemented in alternative architectures.

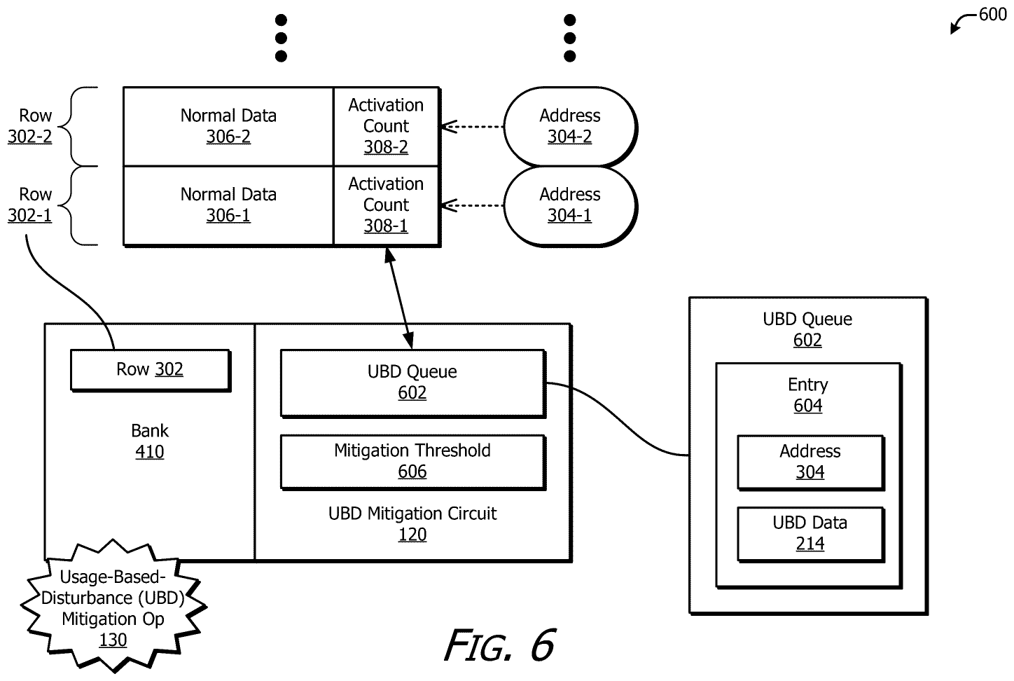

FIG. 6 illustrates, generally at 600, aspects of an example usage-based-disturbance mitigation operation 130 that is performed by an example usage-based-disturbance mitigation circuit 120 to provide example usage-based-disturbance mitigation functionality. As shown, a UBD mitigation circuit 120 corresponds to, or is otherwise associated with, a bank 410 (e.g., also of FIGS. 4 and 5). In example implementations, the UBD mitigation circuit 120 is realized as a bank-level UBD mitigation circuit 120 (e.g., as one of the bank-specific UBD mitigation circuits 120-1 to 120-B of FIG. 5) respectively corresponding to the bank 410. The UBD mitigation circuit 120 can include a usage-based-disturbance queue 602 (UBD queue 602) to facilitate performing the UBD mitigation operation 130. The usage-based-disturbance queue 602 can include multiple entries, such as an entry 604. Each entry 604 can include an address 304 (e.g., at least a row address) of a corresponding row 302 and usage-based-disturbance data 214 for the corresponding row 302. The usage-based-disturbance data 214 can include, for instance, an activation count 308 for the row 302.

In example operations, the UBD mitigation circuit 120 creates or maintains the usage-based-disturbance queue 602. In some cases, the UBD mitigation circuit 120 adds an entry 604 to the usage-based-disturbance queue 602 responsive to an activation count 308 meeting (e.g., equaling or exceeding) a mitigation threshold 606. For instance, each time a row 302 is accessed (e.g., activated), the UBD mitigation circuit 120 can increment the activation count 308 using an activation count update (ACU) unit (not shown) and compare the incremented activation count 308 to the mitigation threshold 606. If the incremented activation count 308 meets the mitigation threshold 606, then an entry 604 is created and added to the usage-based-disturbance queue 602, with the address 304 of the entry 604 corresponding to the accessed row 302. If there is a preexisting entry 604 for the accessed row 302, the activation count 308 of the usage-based-disturbance data 214 of the preexisting entry 604 can be updated.

The incremented activation count 308 is also returned to the row 302 in association with normal data 306 of the row 302. Meanwhile, over time, the usage-based-disturbance queue 602 can be managed in any of multiple manners. First, the queue 602 can be operated in a first-in, first-out (FIFO) manner in which an oldest entry 604 is addressed with a UBD mitigation operation 130 before newer entries. Alternatively, entries may be addressed with a UBD mitigation operation 130 based on the corresponding activation count 308, such as the highest activation count 308 being remediated first. Second, if the usage-based-disturbance queue 602 is full and another row 302 is newly identified for admission as a new entry 604, another entry (e.g., the oldest entry or the entry with the lowest activation count) can be replaced. Alternatively, the newly identified row 302 can be added to the usage-based-disturbance queue 602 conditional on its activation count 308 exceeding those counts that are already present in the queue. In other cases, the UBD mitigation circuit 120 can keep a list of entries 604 in the usage-based-disturbance queue 602 based on multiple mitigation thresholds, a recency indication, no mitigation threshold (e.g., the highest activation counts are maintained without regard to a threshold), or some combination thereof.

From time to time, including during the times that are described herein, the UBD mitigation circuit 120 is assigned an opportunity to perform, or is commanded to perform, a UBD mitigation operation 130. If there is no populated or pending entry 604, the UBD mitigation circuit 120 can pass or skip the mitigation opportunity. For the UBD mitigation operation 130, the UBD mitigation circuit 120 identifies an entry 604 from the usage-based-disturbance queue 602. The identified entry 604 can be selected based on a FIFO approach, based on which activation count 308 is highest, based on a last-in, first-out (LIFO) approach, and so forth. To mitigate the usage-based-disturbance situation, the UBD mitigation circuit 120 refreshes one or more “victim” rows of the row 302 having the address 304 that is identified in the selected entry 604 and that is the aggressor row in this situation.

The one or more row-based memory-cell refresh operations (or charge restore operations) for the UBD mitigation operation 130 can be performed during one or more refresh-pump time intervals. Responsive to performing the one or more refresh operations, the activation count 308 of the aggressor row 302 can be reset (e.g., to zero). Further, the entry 604 can be removed from the usage-based-disturbance queue 602 physically (e.g., by erasing the data of the entry 604 or changing a pointer structure) or virtually/logically (e.g., by adjusting a flag indicating the validity of the entry 604, such as a valid flag bit). Although certain aspects for a UBD mitigation operation 130 have been described herein, these aspects are set forth by way of example only, for a UBD mitigation operation 130 may be performed in various alternative manners. The occurrence of refresh operations for UBD mitigation operations 130 may be varied due to a detection of an application of a UBD pattern by a UBD pattern detection circuit shown in FIG. 7-1 or FIG. 7-2.

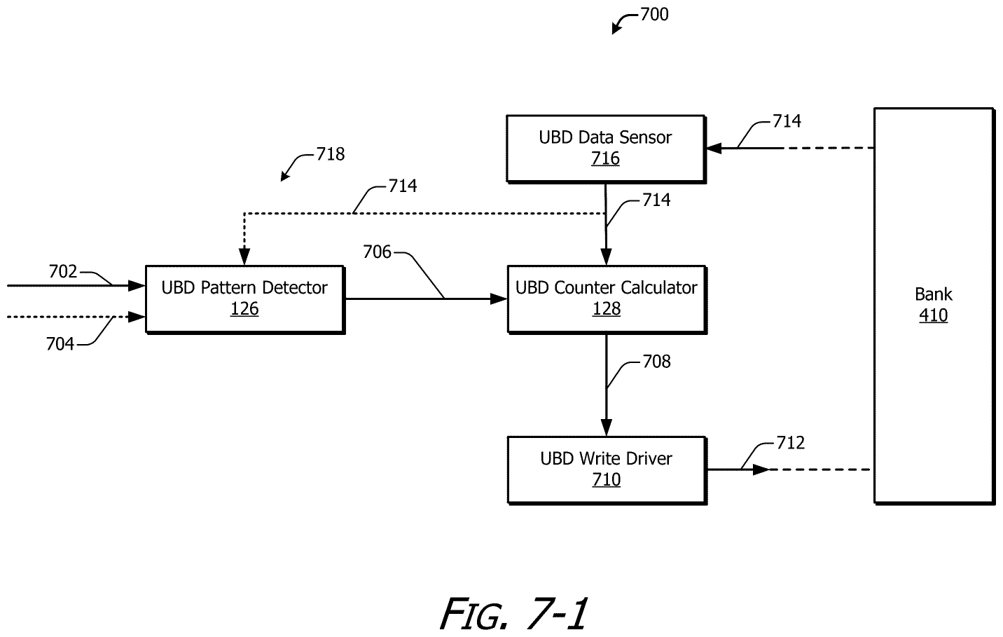

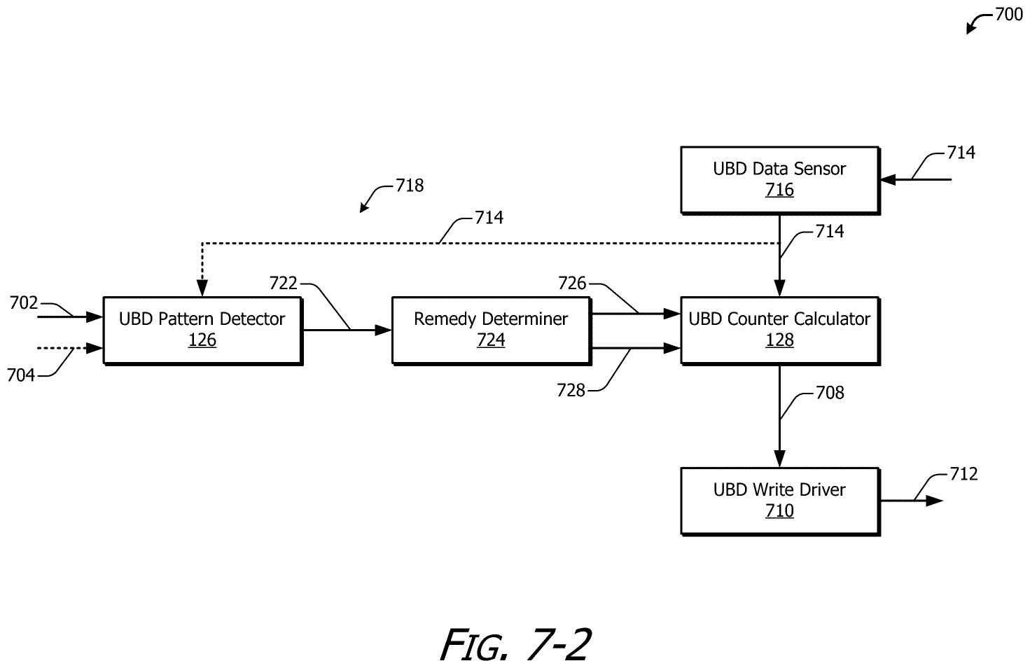

FIG. 7-1 illustrates an example arrangement of components of a UBD pattern detection circuit 700 that can implement aspects of usage-based-disturbance pattern detection and an example bank 410. The UBD pattern detection circuit 700 includes a UBD pattern detector 126. In example implementations, the UBD pattern detector 126 is realized as a bank-level UBD pattern detector 126 (e.g., as one of the bank-specific UBD pattern detector circuits 124-1 to 124-B of FIG. 5) respectively corresponding to the bank 410. The UBD pattern detector 126 is configured to receive a row address 702 of a plurality of rows of memory cells within a memory device. The memory device includes at least one memory bank having a plurality of rows of memory cells. The UBD pattern detector 126 is coupled with the memory bank. The received row address 702 is a row address of the memory device that has been activated (e.g., for a read or other access operation). To determine whether a UBD pattern has been applied to the memory device, the UBD pattern detector 126 compares the received row address 702 to at least one previously received row address stored within the UBD pattern detector 126. Whether or not a UBD pattern has been applied to the memory device is determined based on the comparison. The UBD pattern detector 126 may be configured to receive a memory bank activate command 704 and perform UBD pattern detection responsive to receipt of the memory bank activate command 704.

In one implementation, the UBD pattern detector 126 determines if the received row address 702 is within two (2) row addresses away from the previously received row address stored within the UBD pattern detector 126. If the received row address 702 is within two (2) row addresses away from the previously received stored row address, this may indicate that a pattern, such as alternating double-side attacking discussed herein, has been applied to the memory device. In some cases, the UBD pattern detector 126 determines if the received row address 702 is two (2) row addresses away from the previously received row address stored within the UBD pattern detector 126. For instance, the UBD pattern detector 126 can determine if an absolute value of a difference between the two row addresses equals two (2). Other UBD patterns may be detected by the comparison of the received row address 702 to the stored row address as would be appreciated by one of ordinary skill in the art having the benefit of this disclosure.

In another implementation, the UBD pattern detector 126 may store a plurality of row addresses, each of which may be a previously received row address. The UBD pattern detector 126 is configured to detect if a UBD pattern has been applied to the memory device by comparing the received row address 702 to each of the plurality of row addresses stored within the UBD pattern detector 126.

In yet another implementation, the UBD pattern detector 126 includes a content addressable memory (CAM) configured to store the received row address 702 or a plurality of received row addresses. Alternatively, the UBD pattern detector 126 may include various mechanisms configured to store the received row address 702. For example, the UBD pattern detector 126 may include a latch and a comparator, a register and a comparator, a buffer and a comparator, or the like, each configured to store a previously received row address and to compare the stored previously received row address to the received row address 702 using the comparator.

Upon comparison of the received row address 702, the UBD pattern detector 126 provides a detection indication 706 to a UBD counter calculator 128. The detection indication 706 can indicate to the UBD counter calculator 128 that a UBD pattern has been detected. Upon receipt of the detection indication 706, the UBD counter calculator 128 updates the usage-based-disturbance count using a first value if the UBD pattern is not detected to have been applied and using a second value, which differs from the first value, if the usage-based-disturbance pattern is detected to have been applied. Generally, the second value can be greater than the first value. In one implementation, the first value may be one (1), and the second value may be two (2).

Upon updating the UBD count, the UBD counter calculator 128 provides the updated count 708 to a UBD write driver 710, which writes the updated UBD count 712 as an activation count 308 (e.g., of FIG. 3), or transmits the updated UBD count 712 to an activation count update (ACU) unit (not shown) of the memory device, which updates the activation count 308 accordingly. The UBD mitigation circuit 120 (e.g., of FIG. 6) may indicate to refresh the victim row based on the received count if a mitigation threshold 606 is met or exceeded. During a subsequent memory access cycle for the same row address, a UBD data sensor 716 senses the updated activation count 308 (e.g., of FIG. 6) as updated UBD count 714. The UBD data sensor 716 can forward the updated UBD count 714 to the UBD counter calculator 128. Optionally, the updated UBD count 714 may also be sent to the UBD pattern detector 126 as shown at 718. The UBD pattern detector 126 can use the “current” UBD count 714 to establish a “new” UBD count for implementations in which the detection indication 706 includes an overwrite value instead of an increase value (or decrease value).

FIG. 7-2 illustrates an example arrangement of components of a UBD pattern detection circuit 700 that can implement aspects of usage-based-disturbance pattern detection for a memory device including at least one memory bank having a plurality of rows of memory cells. The UBD pattern detection circuit 700 includes a UBD pattern detector 126 coupled with the memory bank and configured to receive a row address 702 of a plurality of rows of memory cells. The received row address 702 is a row address of the memory device that has been activated, and the UBD pattern detector 126 compares the received row address 702 to at least one row address stored within the UBD pattern detector 126. Whether or not a UBD pattern has been applied to the memory device is determined based on the comparison. The UBD pattern detector 126 may be configured to receive a memory bank activate command 704 and perform UBD pattern detection responsive to receipt of the memory bank activate command 704.

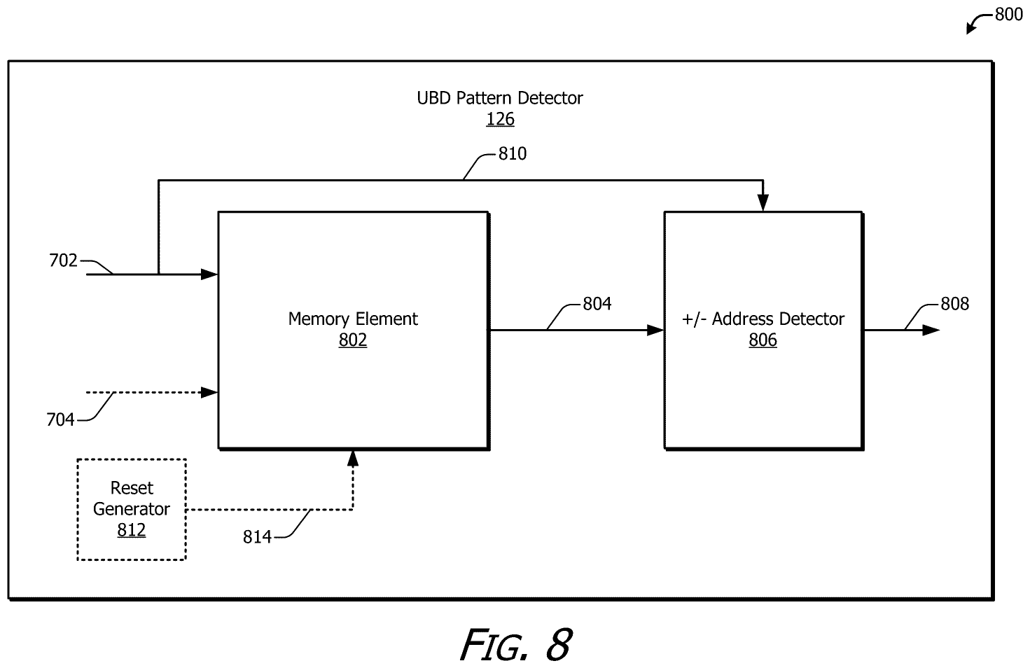

The UBD pattern detector 126 can be configured to send to a remedy determiner 724 an indication 722 of whether or not a UBD pattern has been detected. The indication 722 may be an indication of how a UBD count 122 is to be updated, such as responsive to a UBD pattern detection or the absence of such a detection. Based on the indication 722, the remedy determiner 724 may be configured to increase the UBD count 122 by one of two or more amounts, decrease the UBD count 122 by one of two or more amounts, or overwrite the UBD count 122 to one of two or more amounts. The remedy determiner 724 transmits a UBD count value 726 and a remedy operation 728 (e.g., whether to increase the usage-based-disturbance count, decrease the usage-based-disturbance count, or overwrite the usage-based-disturbance count) to the UBD counter calculator 128. Based on the UBD count value 726 and the remedy operation 728, the UBD counter calculator 128 updates the BUD count 714 to produce the updated UBD count 708. The UBD write driver 710 then writes the updated UBD count 708 as a new activation count 308 in association with the row 302 that corresponds to the row address 702. One implementation of a UBD pattern detector 126 that may be used in the UBD pattern detection circuit 700 is shown in FIG. 8.

FIG. 8 illustrates an example implementation 800 of a UBD pattern detector 126 that can implement aspects of usage-based-disturbance pattern detection. The UBD pattern detector 126 includes a memory element 802 configured to store a received row address 702. The received row address 702 indicates the address of a row of memory cells of a memory bank that has been activated. The memory element 802 may be a content addressable memory, a latch and a comparator, a register and a comparator, a buffer and a comparator, or the like.

The memory element 802 may send a stored row address 804, or previously received row address 804, to a +/− address detector 806. The +/− address detector 806 may also receive the received row address 702 as a signal 810. The +/− address detector 806 may be configured to compare the signal 810 (e.g., the received address 702) with the stored address 804 to detect whether a UBD pattern has been applied to a memory device. For example, the +/− address detector 806 may be configured to determine whether the signal 810 (e.g., the received address 702) is within 2 row addresses away from the stored address 804, including being two row addresses apart. If a difference between two row addresses is two (2), then one row (e.g., a potential victim row) separates the two rows corresponding to the two row addresses, which may reveal an alternately row-activating attack pattern. A range of comparisons of addresses by the +/− address detector 806 may be varied as would be appreciated by one of ordinary skill in the art having the benefit of this disclosure. The +/− address detector 806 may be configured to provide an indication 808 of whether a UBD pattern is detected or not detected based on the comparison. The indication 808 can correspond to the detection indication 706 or 722 (e.g., of FIG. 7-1 or 7-2).

The UBD pattern detector 126 may optionally include a reset generator 812 coupled with the memory element 802. The reset generator 812 is configured to send a reset signal 814 to the memory element 802 to reset previously received row address(es) stored within the memory element 802. The reset generator 812 may be configured to send the reset signal 814 after a predetermined time period. Additionally or alternatively, the reset generator 812 may be configured to send the reset signal 814 responsive to a DRAM command.

### EXAMPLE METHODS

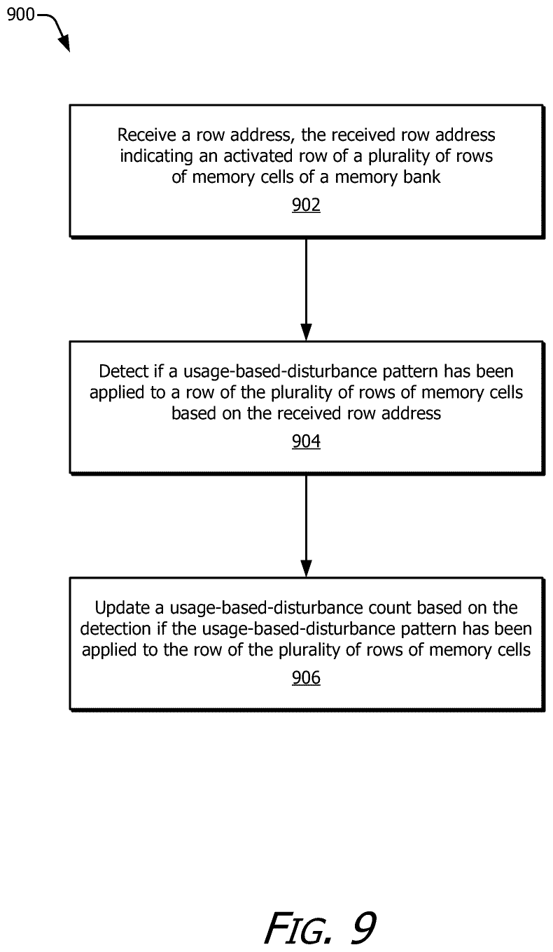

This section describes example methods for implementing aspects of detection of usage-based-disturbance patterns with reference to the diagrams of FIGS. 9 to 11. This description may also refer to components, entities, and other aspects depicted in FIGS. 1 to 8 by way of example only. The described methods are not necessarily limited to performance by one entity or multiple entities operating on one device.

FIG. 9 illustrates a method 900, which includes operations 902 through 906. In aspects, operations of the method 900 are implemented by a memory device 108 as described with reference to FIG. 1. At 902, a row address is received, with the received row address indicating an activation row of a plurality of rows of memory cells of a memory bank. For example, a UBD pattern detector 126 can receive a row address 702, which indicates a row 302 of a plurality of rows of memory cells of a memory bank 410 that has been activated.

At 904, based on the received row address, it is detected if a usage-based-disturbance pattern has been applied to a row of the plurality of rows of memory cells. For example, the UBD pattern detector 126 can detect if a usage-based-disturbance pattern has been applied to a row 302 of the plurality of the rows of memory cells of a memory bank 410 based on the received row address 702. For instance, the UBD pattern detector 126 may compare the received row address 702 to a previously received row address to determine if a particular difference between the two row addresses exists.

At 906, a usage-based-disturbance count is updated based on the detection if the usage-based-disturbance pattern has been applied to the row of the plurality of rows of memory cells. For example, a UBD counter calculator 128 can update a usage-based-disturbance count 122 if the UBD pattern detector 126 detects that a UBD pattern has been applied to the row 302 of the plurality of rows of memory cells of the memory device.

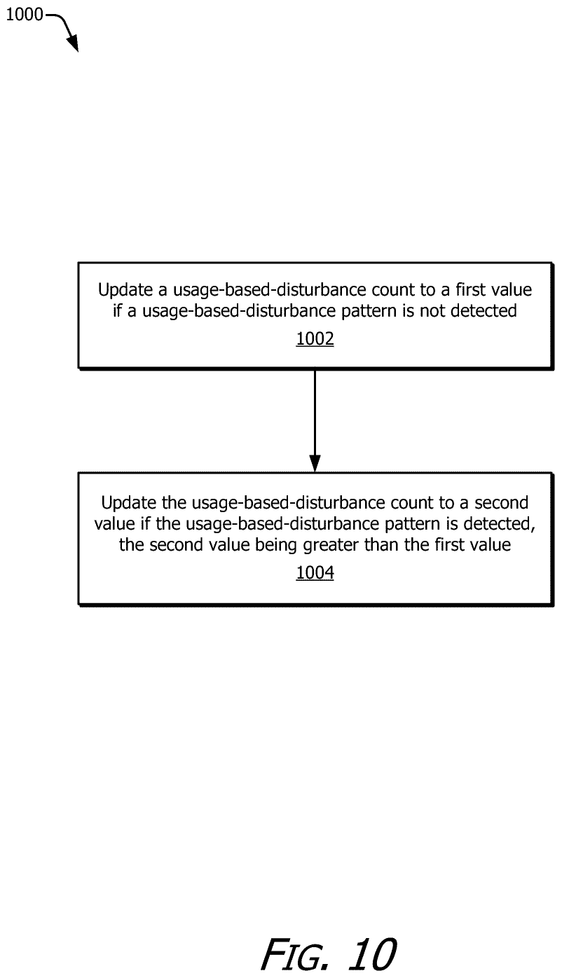

FIG. 10 illustrates a method 1000, which includes operations 1002 and 1004 and can be a continuation of the method 900 of FIG. 9. In aspects, operations of the method 1000 are implemented by a memory device 108 as described with reference to FIG. 1. At 1002, a usage-based-disturbance count is updated using a first value if a usage-based-disturbance pattern is not detected. For example, if the UBD pattern detector 126 does not detect a UBD pattern, the UBD count 122 can be updated using a first value (e.g., updated with a value of 1). At 1004, the usage-based-disturbance count is updated using a second value if the usage-based-disturbance pattern is detected, with the second value being greater than the first value. For example, if the UBD pattern detector 126 does detect a UBD pattern, the UBD count 122 can be updated using a second value (e.g., updated with a value of 2 to increase the activation count more quickly to account for the UBD pattern).

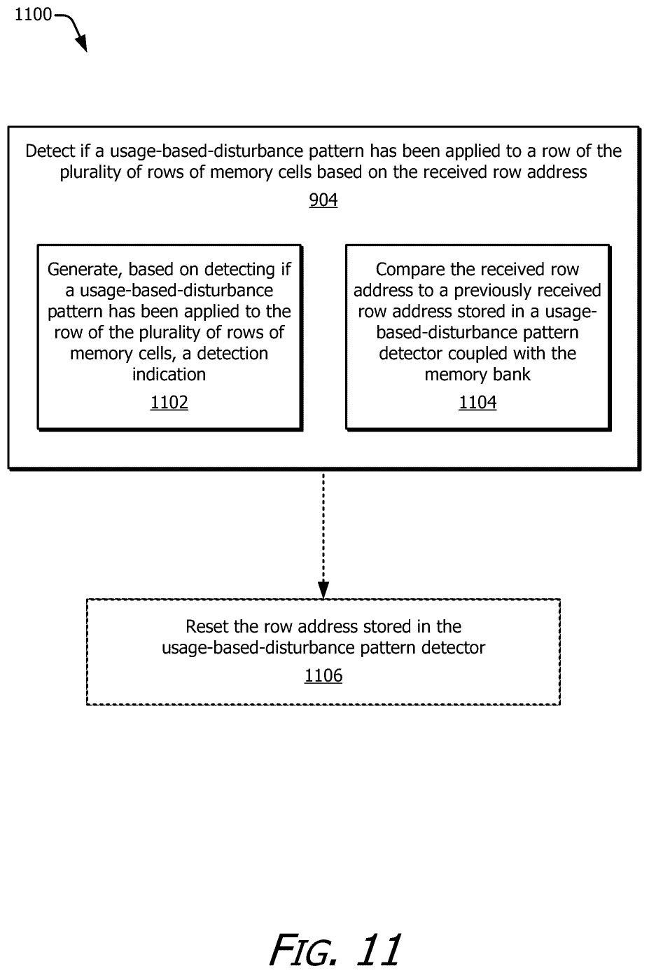

FIG. 11 illustrates a method 1100, which includes operations 1102 through 1106 and can be a continuation of the method 900 of FIG. 9 and/or the method 1000 of FIG. 10. In aspects, operations of the method 1100 are implemented by a memory device 108 as described with reference to FIG. 1. At 1102, a detection indication is generated based on detecting if a usage-based-disturbance pattern has been applied to the row of the plurality of rows of memory cells. For example, the UBD pattern detector 126 can generate a detection indication (e.g., the indication 706 or the indication 722) upon detection that a UBD pattern has been applied to a row of the plurality of rows of memory cells, with the detection indication 706 being an affirmative detection indication in this case.

At 1104, to detect a UBD pattern, the received row address is compared to a previously received row address stored in a usage-based-disturbance pattern detector coupled with the memory bank. For example, the received row address (e.g., the received row address 702) can be compared with a stored previously received row address within the UBD pattern detector 126 to determine if a particular row address relationship exists between the two row addresses.

At 1106, the row address stored in the usage-based-disturbance pattern detector may be optionally reset. For example, a reset generator 812 may optionally send a reset signal 814 to a memory element 802 of the UBD pattern detector 126 to reset row addresses stored within the memory element 802. The reset signal 814 may be sent after a predetermined time period or upon receipt of a DRAM command.

For the figures described above, the order in which operations are shown and/or described is not intended to be construed as a limitation. Any number or combinations of the described process operations can be combined or rearranged in any order to implement a given method or an alternative method. Operations may also be omitted from or added to the described methods. Further, described operations can be implemented in fully or partially overlapping manners.

Aspects of these methods may be implemented in, for example, hardware (e.g., fixed-circuit circuitry or a processor in conjunction with a memory), firmware, software, or some combination thereof. The methods may be realized using one or more of the apparatuses, components, or other aspects shown in FIGS. 1 to 8, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media include both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of usage-based-disturbance pattern detection are described:

Example 1: An apparatus comprising:
a memory device comprising:
at least one memory bank comprising a plurality of rows of memory cells;
a usage-based-disturbance pattern detector coupled with the at least one memory bank, the usage-based-disturbance pattern detector configured to:
   receive a row address;
   detect if a usage-based-disturbance pattern has been applied to a row of the plurality of rows of memory cells based on the received row address; and
   a usage-based-disturbance counter calculator coupled with the usage-based-disturbance pattern detector, the usage-based-disturbance counter calculator configured to update a usage-based-disturbance count based on the detection.

Example 2: The apparatus of example 1 or any other example(s) described herein, wherein the usage-based-disturbance counter calculator is configured to:
update the usage-based-disturbance count using a first value if the usage-based-disturbance pattern is not detected to have been applied; and
update the usage-based-disturbance count using a second value if the usage-based-disturbance pattern is detected to have been applied, the second value being different than the first value.

Example 3: The apparatus of example 2 or any other example(s) described herein, wherein the first value is one (1), and the second value is two (2).

Example 4: The apparatus of example 2 or any other example(s) described herein, wherein the usage-based-disturbance pattern detector is configured to:
receive a memory bank activate command; and
perform the detection responsive to receipt of the memory bank activate command.

Example 5: The apparatus of example 2 or any other example(s) described herein, wherein:
the memory device further comprises a remedy determiner coupled with the usage-based-disturbance pattern detector and the usage-based-disturbance counter calculator, the remedy determiner configured to generate, based on the detection, an update indication; and
the usage-based-disturbance counter calculator is configured to update the usage-based-disturbance count based on the update indication.

Example 6: The apparatus of example 5 or any other example(s) described herein, wherein the update indication comprises at least one of:
an indication to increase the usage-based-disturbance count;
an indication to decrease the usage-based-disturbance count; or
an indication to overwrite the usage-based-disturbance count.

Example 7: The apparatus of example 2 or any other example(s) described herein, wherein:
the usage-based-disturbance pattern detector further comprises a memory configured to store at least one row address, the at least one row address comprising a previously received row address; and
the usage-based-disturbance pattern detector is configured to detect application of the usage-based-disturbance pattern based on at least one comparison of the received row address to the previously received row address.

Example 8: The apparatus of example 7 or any other example(s) described herein, wherein the memory configured to store the at least one row address comprises at least one of:
a content addressable memory;
a latch and a comparator;
a register and a comparator; or
a buffer and a comparator.

Example 9: The apparatus of example 7 or any other example(s) described herein, wherein application of the usage-based-disturbance pattern is detected responsive to the received row address being within two (2) addresses away from the previously received row address stored within the memory.

Example 10: The apparatus of example 7 or any other example(s) described herein, wherein the memory is configured to store a plurality of row addresses, the plurality of row addresses comprising a plurality of previously received row addresses.

Example 11: The apparatus of example 10 or any other example(s) described herein, wherein the usage-based-disturbance pattern detector is configured to detect application of the usage-based-disturbance pattern based on one or more comparisons of the received row address to the plurality of previously received row addresses.

Example 12: The apparatus of example 7 or any other example(s) described herein, wherein:
the memory device further comprises a reset generator coupled with the memory; and
the reset generator is configured to reset the previously received row address stored within the memory after a predetermined time period or responsive to a dynamic random-access memory (DRAM) command.

Example 13: A method comprising:
receiving a row address, the received row address indicating an activated row of a plurality of rows of memory cells of a memory bank;
detecting if a usage-based-disturbance pattern has been applied to a row of the plurality of rows of memory cells based on the received row address; and
updating a usage-based-disturbance count based on the detecting if the usage-based-disturbance pattern has been applied to the row of the plurality of rows of memory cells.

Example 14: The method of example 13 or any other example(s) described herein, wherein updating the usage-based-disturbance count comprises:
updating the usage-based-disturbance count using a first value if the usage-based-disturbance pattern is not detected; and
updating the usage-based-disturbance count using a second value if the usage-based-disturbance pattern is detected, the second value being greater than the first value.

Example 15: The method of example 13 or any other example(s) described herein, further comprising:
generating, based on the detecting if the usage-based-disturbance pattern has been applied to the row of the plurality of rows of memory cells, a detection indication,
wherein updating the usage-based-disturbance count is based on the detection indication.

Example 16: The method of example 13 or any other example(s) described herein, wherein detecting if the usage-based-disturbance pattern has been applied comprises:
comparing the received row address to a previously received row address stored in a usage-based-disturbance pattern detector coupled with the memory bank.

Example 17: The method of example 16 or any other example(s) described herein, further comprising:
resetting the previously received row address stored in the usage-based-disturbance pattern detector based on a predetermined time period or receipt of a dynamic random-access memory (DRAM) command.

Example 18: The method of example 13 or any other example(s) described herein, wherein detecting if the usage-based-disturbance pattern has been applied comprises:
comparing the received row address to a plurality of previously received row addresses stored in a usage-based-disturbance pattern detector coupled with the memory bank.

Example 19: An apparatus comprising:
a memory device comprising:
   at least one memory array including:
      multiple rows including memory cells; and
      multiple counters, each respective counter corresponding to a respective row of the multiple rows and configured to store a respective usage-based-disturbance count associated with the respective row;
   a memory configured to store at least one previous row address; and
   logic coupled to the memory and the at least one memory array, the logic configured to:
      perform a comparison including a current row address and the at least one previous row address; and
      adjust a usage-based-disturbance count associated with a current row corresponding to the current row address based on the comparison.

Example 20: The apparatus of example 19 or any other example(s) described herein, wherein the logic is configured to:
perform the comparison by determining a difference between the current row address and the at least one previous row address;
adjust the usage-based-disturbance count using a first value responsive to the difference being equal to at least one predetermined value; and
adjust the usage-based-disturbance count using a second value responsive to the difference not being equal to the at least one predetermined value, the second value being different than the first value.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although aspects of usage-based-disturbance pattern detection have been described in language specific to certain features and/or methods, the subject of the appended claims is not necessarily limited to the specific features or methods described. Rather, the specific features and methods are disclosed as a variety of example implementations of usage-based-disturbance pattern detection.

What is claimed is:

1. An apparatus comprising:
a memory device comprising:
at least one memory bank comprising a plurality of rows of memory cells;
a usage-based-disturbance pattern detector coupled with the at least one memory bank, the usage-based-disturbance pattern detector configured to:
receive a row address; and
detect if a usage-based-disturbance pattern has been applied to a row of the plurality of rows of memory cells based on the received row address; and
a usage-based-disturbance counter calculator coupled with the usage-based-disturbance pattern detector, the usage-based-disturbance counter calculator configured to update a usage-based-disturbance count based on the detection.

2. The apparatus of claim 1, wherein the usage-based-disturbance counter calculator is configured to:
update the usage-based-disturbance count using a first value if the usage-based-disturbance pattern is not detected to have been applied; and
update the usage-based-disturbance count using a second value if the usage-based-disturbance pattern is detected to have been applied, the second value being different than the first value.

3. The apparatus of claim 2, wherein the first value is one (1), and the second value is two (2).

4. The apparatus of claim 2, wherein the usage-based-disturbance pattern detector is configured to:
receive a memory bank activate command; and
perform the detection responsive to receipt of the memory bank activate command.

5. The apparatus of claim 2, wherein:
the memory device further comprises a remedy determiner coupled with the usage-based-disturbance pattern detector and the usage-based-disturbance counter calculator, the remedy determiner configured to generate, based on the detection, an update indication; and
the usage-based-disturbance counter calculator is configured to update the usage-based-disturbance count based on the update indication.

6. The apparatus of claim 5, wherein the update indication comprises at least one of:
an indication to increase the usage-based-disturbance count;
an indication to decrease the usage-based-disturbance count; or
an indication to overwrite the usage-based-disturbance count.

7. The apparatus of claim 2, wherein:
the usage-based-disturbance pattern detector comprises a memory configured to store at least one row address, the at least one row address comprising a previously received row address; and
the usage-based-disturbance pattern detector is configured to detect application of the usage-based-disturbance pattern based on at least one comparison of the received row address to the previously received row address.

8. The apparatus of claim 7, wherein the memory configured to store the at least one row address comprises at least one of:
a content addressable memory;
a latch and a comparator;
a register and a comparator; or
a buffer and a comparator.

9. The apparatus of claim 7, wherein application of the usage-based-disturbance pattern is detected responsive to the received row address being within two (2) addresses away from the previously received row address stored within the memory.

10. The apparatus of claim 7, wherein the memory is configured to store a plurality of row addresses, the plurality of row addresses comprising a plurality of previously received row addresses.

11. The apparatus of claim 10, wherein the usage-based-disturbance pattern detector is configured to detect application of the usage-based-disturbance pattern based on one or more comparisons of the received row address to the plurality of previously received row addresses.

12. The apparatus of claim 7, wherein:
the memory device further comprises a reset generator coupled with the memory; and
the reset generator is configured to reset the previously received row address stored within the memory after a predetermined time period or responsive to a dynamic random-access memory (DRAM) command.

13. A method comprising:
receiving a row address, the received row address indicating an activated row of a plurality of rows of memory cells of a memory bank;
detecting if a usage-based-disturbance pattern has been applied to a row of the plurality of rows of memory cells based on the received row address; and
updating a usage-based-disturbance count based on the detecting if the usage-based-disturbance pattern has been applied to the row of the plurality of rows of memory cells.

14. The method of claim 13, wherein updating the usage-based-disturbance count comprises:
updating the usage-based-disturbance count using a first value if the usage-based-disturbance pattern is not detected; and
updating the usage-based-disturbance count using a second value if the usage-based-disturbance pattern is detected, the second value being greater than the first value.

15. The method of claim 13, further comprising:
generating, based on the detecting if the usage-based-disturbance pattern has been applied to the row of the plurality of rows of memory cells, a detection indication,
wherein updating the usage-based-disturbance count is based on the detection indication.

16. The method of claim 13, wherein detecting if the usage-based-disturbance pattern has been applied comprises:
comparing the received row address to a previously received row address stored in a usage-based-disturbance pattern detector coupled with the memory bank.

17. The method of claim 16, further comprising:
resetting the previously received row address stored in the usage-based-disturbance pattern detector based on a predetermined time period or receipt of a dynamic random-access memory (DRAM) command.

18. The method of claim 13, wherein detecting if the usage-based-disturbance pattern has been applied comprises:
comparing the received row address to a plurality of previously received row addresses stored in a usage-based-disturbance pattern detector coupled with the memory bank.

19. An apparatus comprising:
a memory device comprising:
at least one memory array including:
multiple rows including memory cells; and
multiple counters, each respective counter corresponding to a respective row of the multiple rows and configured to store a respective usage-based-disturbance count associated with the respective row;
a memory configured to store at least one previous row address; and
logic coupled to the memory and the at least one memory array, the logic configured to:
perform a comparison including a current row address and the at least one previous row address; and
adjust a usage-based-disturbance count associated with a current row corresponding to the current row address based on the comparison.

20. The apparatus of claim 19, wherein the logic is configured to:
perform the comparison by determining a difference between the current row address and the at least one previous row address;
adjust the usage-based-disturbance count using a first value responsive to the difference being equal to at least one predetermined value; and
adjust the usage-based-disturbance count using a second value responsive to the difference not being equal to the at least one predetermined value, the second value being different than the first value.
